(19) United States
(12) Patent Application Publication
(10) Pub. No.: US 2010/0078763 A1
(43) Pub. Date: Apr. 1, 2010

(54) RESISTANCE-CHANGE MEMORY HAVING RESISTANCE-CHANGE ELEMENT AND MANUFACTURING METHOD THEREOF

(75) Inventors: Keiji HOSOTANI, Palo Alto, CA (US); Yoshiaki ASAO, Sagamihara-shi (JP); Kuniaki SUGIURA, Fujisawa-shi (JP); Masatoshi YOSHIKAWA, Yokohama-shi (JP); Sumio IKEGAWA, Yokohama-shi (JP); Shigeki TAKAHASHI, Yokohama-shi (JP); Minoru AMANO, Sagamihara-shi (JP)

Correspondence Address: KNOBBE MARTENS OLSON & BEAR LLP, 2040 MAIN STREET, FOURTEENTH FLOOR, IRVINE, CA, 92614, US

(73) Assignee: KABUSHIKI KAISHA TOSHIBA, Tokyo (JP)

(21) Appl. No.: 12/559,446

(22) Filed: Sep. 14, 2009

(30) Foreign Application Priority Data
Sep. 29, 2008 (JP) 2008-250230

(51) Int. Cl. H01L 29/86; H01L 21/8239

(52) U.S. Cl. 257/537; 438/384; 257/295; 438/3; 257/E21.645; 257/E29.325; 257/E21.006

(57) ABSTRACT

A resistance-change memory includes an interlayer insulating film, a lower electrode layer, a fixed layer, a first insulating film, a recording layer, a second insulating film, a conducting layer and an interconnect. The interlayer insulating film is formed on a semiconductor substrate and has a step. The lower electrode layer is formed on the interlayer insulating film including the step. The fixed layer is formed on the lower electrode layer and has invariable magnetization. The first insulating film is formed on the fixed layer. The recording layer is formed on part of the first insulating film and has variable magnetization. The second insulating film is over the recording layer and in contact with the first insulating film. The conducting layer is formed on the second insulating film. The interconnect is connected to the conducting layer.

### CROSS-REFERENCE TO RELATED APPLICATIONS

This application is based upon and claims the benefit of priority from prior Japanese Patent Application No. 2008-250230, filed Sep. 29, 2008, the entire contents of which are incorporated herein by reference.

### BACKGROUND OF THE INVENTION

1. Field of the Invention

The present invention relates to a resistance-change memory having a resistance-change element formed on a step, and a manufacturing method thereof.

2. Description of the Related Art

As one kind of resistance-change memory, there is a magnetoresistive random access memory (MRAM) which utilizes the tunneling magnetoresistive effect (TMR). Researches are actively conducted around the world for the practical use of the MRAM. The technical application of the MRAM has been expanding, and the MRAMs, which currently have a small scale of 4 megabits, are mass-produced and sold as chips (e.g., see ISSCC 2000 Technical Digest p. 128 “A 10 ns Read and Write Non-Volatile Memory Array Using a Magnetic Tunnel Junction and FET Switch in each Cell” and M. Durlam et al., “A 0.18 μm 4 Mb Toggling MRAM”, IEDM 2003 Proceedings, 34.6, December 2003.).

In connection with this MRAM, a spin-injection MRAM which utilizes the operation principle of “spin injection magnetization inversion” is regarded as a promising technique to obtain a large-scale memory.

However, in the case of the conventional spin-injection MRAM, the size of a magnetic tunnel junction (MTJ) element is regulated by the limitation of normal microfabrication processes such as lithography and etching. Therefore, it is difficult to achieve microfabrication that can bring out sufficient characteristics of an element as a spin-injection MRAM.

### BRIEF SUMMARY OF THE INVENTION

According to a first aspect of the present invention, there is provided a resistance-change memory comprising: an interlayer insulating film formed on a semiconductor substrate and having a step; a lower electrode layer formed on the interlayer insulating film including the step; a fixed layer formed on the lower electrode layer and having invariable magnetization; a first insulating film formed on the fixed layer; a recording layer formed on part of the first insulating film and having variable magnetization; a second insulating film over the recording layer and in contact with the first insulating film; a conducting layer formed on the second insulating film; and an interconnect connected to the conducting layer.

According to a second aspect of the present invention, there is provided a resistance-change memory comprising: an interlayer insulating film formed on a semiconductor substrate and having a step; a lower electrode layer formed on the interlayer insulating film including the step; a fixed layer formed on the lower electrode layer and having invariable magnetization; a first insulating film formed on the fixed layer; a recording layer formed on part of the first insulating film and having variable magnetization; a second insulating film over the recording layer and in contact with the first insulating film; a third insulating film formed on the sidewall of the second insulating film; and an interconnect connected to the recording layer via the second insulating film.

According to a third aspect of the present invention, there is provided a resistance-change memory comprising: an interlayer insulating film formed on a semiconductor substrate and having a step; a lower electrode layer formed on the interlayer insulating film including the step; a first insulating film formed on the lower electrode layer; a recording layer formed on part of the first insulating film and having variable magnetization; a second insulating film over the recording layer and in contact with the first insulating film; a fixed layer formed on the second insulating film and having invariable magnetization; and an interconnect connected to the fixed layer.

According to a fourth aspect of the present invention, there is provided a method of manufacturing a resistance-change memory, the method comprising: forming a first interlayer insulating film having a step on a semiconductor substrate; forming a lower electrode layer on the step; stacking a fixed layer, a first insulating film and a recording layer on the lower electrode layer in order; agglomerating the recording layer on the step by a thermal treatment; stacking a second insulating film and a conducting layer on the recording layer and the first insulating film; processing the second insulating film and the conducting layer to be left on the step; processing the first insulating film, the fixed layer and the lower electrode layer to be left on the step to form a resistance-change element; forming a second interlayer insulating film over the resistance-change element; planarizing the second interlayer insulating film to expose the conducting layer; and forming an interconnect on the exposed upper surface of the conducting layer.

According to a fifth aspect of the present invention, there is provided a method of manufacturing a resistance-change memory, the method comprising: forming a first interlayer insulating film having a step on a semiconductor substrate; forming a lower electrode layer on the step; stacking a fixed layer, a first insulating film and a recording layer on the lower electrode layer in order; agglomerating the recording layer on the step by a thermal treatment; stacking second and third insulating films on the recording layer and the first insulating film; processing the second and third insulating films to be left on the step; processing the first insulating film, the fixed layer and the lower electrode layer to be left on the step to form a resistance-change element; forming a second interlayer insulating film over the resistance-change element; planarizing the second interlayer insulating film to expose one of the second insulating film and the recording layer; and forming an interconnect on the exposed upper surface of one of the second insulating film and the recording layer.

### BRIEF DESCRIPTION OF THE SEVERAL VIEWS OF THE DRAWING

FIGS. 1A and 1B are a sectional view and a planar view showing a magnetic random access memory according to a first embodiment of the present invention;

FIGS. 2A and 2B are a sectional view and a planar view showing the process of manufacturing the magnetic random access memory according to the first embodiment;

FIGS. 3A and 3B are a sectional view and a planar view, following FIGS. 2A and 2B, showing the process of manufacturing the magnetic random access memory according to the first embodiment;

FIGS. 4A and 4B are a sectional view and a planar view, following FIGS. 3A and 3B, showing the process of manufacturing the magnetic random access memory according to the first embodiment;

FIGS. 5A and 5B are a sectional view and a planar view, following FIGS. 4A and 4B, showing the process of manufacturing the magnetic random access memory according to the first embodiment;

FIGS. 6A and 6B are a sectional view and a planar view showing the magnetic random access memory according to the first embodiment;

FIGS. 7A and 7B are a sectional view and a planar view showing a magnetic random access memory according to a second embodiment of the present invention;

FIGS. 8A and 8B are a sectional view and a planar view showing the magnetic random access memory according to the second embodiment;

FIGS. 9A and 9B are a sectional view and a planar view, following FIGS. 8A and 8B, showing the process of manufacturing the magnetic random access memory according to the second embodiment;

FIGS. 10A and 10B are a sectional view and a planar view, following FIGS. 9A and 9B, showing the process of manufacturing the magnetic random access memory according to the second embodiment;

FIGS. 11A and 11B are a sectional view and a planar view, following FIGS. 10A and 10B, showing the process of manufacturing the magnetic random access memory according to the second embodiment;

FIGS. 12A and 12B are a sectional view and a planar view showing another magnetic random access memory according to the second embodiment;

FIGS. 13A and 13B are a sectional view and a planar view showing a magnetic random access memory according to a third embodiment of the present invention;

FIGS. 14A and 14B are a sectional view and a planar view showing the process of manufacturing the magnetic random access memory according to the third embodiment;

FIGS. 15A and 15B are a sectional view and a planar view, following FIGS. 10A and 10B, showing the process of manufacturing the magnetic random access memory according to the third embodiment;

FIGS. 16A and 16B are a sectional view and a planar view, following FIGS. 15A and 15B, showing the process of manufacturing the magnetic random access memory according to the third embodiment;

FIGS. 17A and 17B are a sectional view and a planar view, following FIGS. 16A and 16B, showing the process of manufacturing the magnetic random access memory according to the third embodiment;

FIGS. 18A and 18B are a sectional view and a planar view showing another magnetic random access memory according to the third embodiment;

FIGS. 19A and 19B are a sectional view and a planar view showing a magnetic random access memory according to a fourth embodiment of the present invention;

FIGS. 20A and 20B are a sectional view and a planar view showing the process of manufacturing the magnetic random access memory according to the fourth embodiment;

FIGS. 21A and 21B are a sectional view and a planar view, following FIGS. 20A and 20B, showing the process of manufacturing the magnetic random access memory according to the fourth embodiment;

FIGS. 22A and 22B are a sectional view and a planar view, following FIGS. 21A and 21B, showing the process of manufacturing the magnetic random access memory according to the fourth embodiment;

FIGS. 23A and 23B are a sectional view and a planar view, following FIGS. 22A and 22B, showing the process of manufacturing the magnetic random access memory according to the fourth embodiment;

FIGS. 24A and 24B are a sectional view and a planar view showing another magnetic random access memory according to the fourth embodiment;

FIG. 25 is a sectional view showing a magnetic random access memory according to a fifth embodiment of the present invention;

FIG. 26 is a sectional view showing the process of manufacturing a magnetic random access memory according to the fifth embodiment;

FIG. 27 is a sectional view, following FIG. 26, showing the process of manufacturing the magnetic random access memory according to the fifth embodiment;

FIG. 28 is a sectional view, following FIG. 27, showing the process of manufacturing the magnetic random access memory according to the fifth embodiment;

FIG. 29 is a sectional view, following FIG. 28, showing the process of manufacturing the magnetic random access memory according to the fifth embodiment;

FIG. 30 is a sectional view showing a magnetic random access memory according to a sixth embodiment of the present invention;

FIG. 31 is a sectional view showing the process of manufacturing the magnetic random access memory according to the sixth embodiment;

FIG. 32 is a sectional view, following FIG. 31, showing the process of manufacturing the magnetic random access memory according to the sixth embodiment;

FIG. 33 is a sectional view, following FIG. 32, showing the process of manufacturing the magnetic random access memory according to the sixth embodiment;

FIG. 34 is a sectional view, following FIG. 33, showing the process of manufacturing the magnetic random access memory according to the sixth embodiment;

FIG. 35 is a sectional view showing a schematic memory cell of the magnetic random access memory according to the embodiments of the present invention;

FIG. 36 is a view showing spin injection magnetization inversion writing of the magnetic random access memory according to the embodiments;

FIG. 37 is a view showing the spin injection magnetization inversion writing of the magnetic random access memory according to the embodiments;

FIG. 38 is a view showing TMR-effect-based reading of the magnetic random access memory according to the embodiments; and

FIG. 39 is a view showing the TMR-effect-based reading of the magnetic random access memory according to the embodiments.

### DETAILED DESCRIPTION OF THE INVENTION

Embodiments of the present invention will hereinafter be described with reference to the drawings.

In this description, like reference numbers are assigned to like parts throughout the drawings.

### [1] First Embodiment

In the first embodiment, when MTJ elements separated cell by cell are formed by agglomeration, projecting steps are formed in the foundations of the MTJ elements.

[1-1] Structure

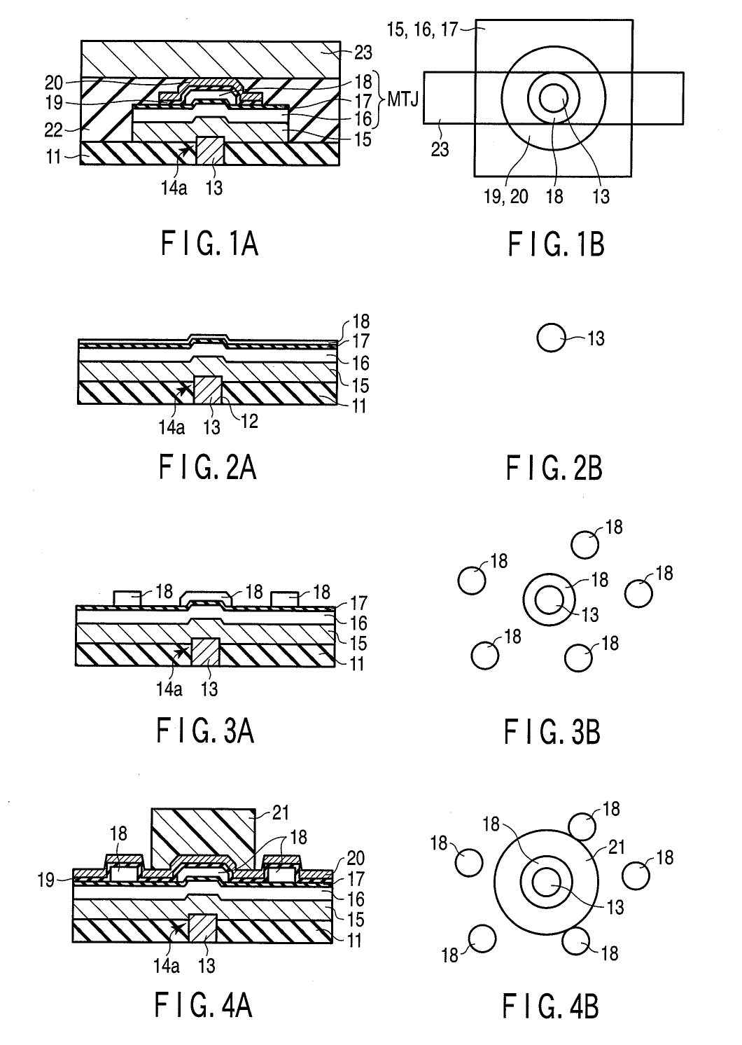

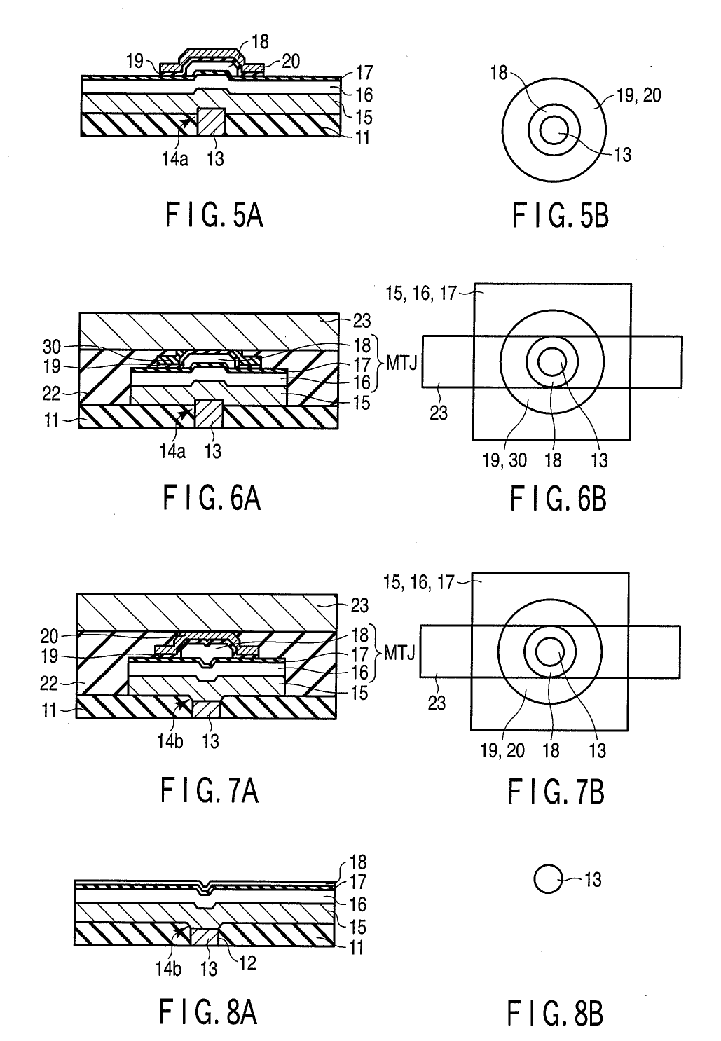

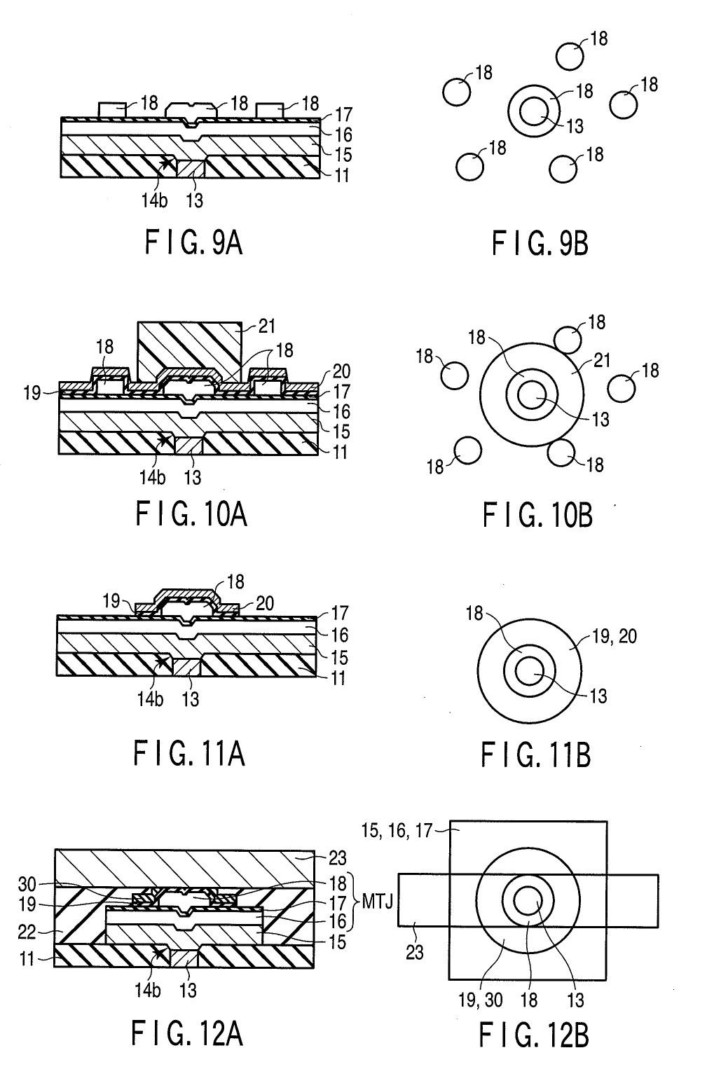

FIGS. 1A and 1B are a sectional view and a planar view showing a magnetic random access memory according to the first embodiment of the present invention. The structure of the magnetic random access memory according to the first embodiment is described below.

As shown in FIGS. 1A and 1B, a contact plug 13 is formed in an interlayer insulating film 11, and a lower electrode layer 15 is formed on this contact plug 13. An MTJ element MTJ is formed on the lower electrode layer 15, and a bit line 23 is formed on this MTJ element MTJ via an insulating gap layer 19 and a conducting gap layer 20.

The MTJ element MTJ has a fixed layer 16, a recording layer 18, and a tunnel insulating film 17 formed between the fixed layer 16 and the recording layer 18. The fixed layer 16 is located below the recording layer 18 and formed closer to the contact plug 13 than the recording layer 18. The fixed layer 16 is a ferromagnetic material functioning as a referential layer having sustained magnetization, and has its magnetization fixed in a predetermined direction. The recording layer 18 is a ferromagnetic material functioning as a free layer having changing magnetization, and has the magnetization direction changed by a magnetic field provided from the outside or by spin injection. In other words, the fixed layer 16 has variable magnetization and the recording layer 18 has invariable magnetization.

The upper surface of the contact plug 13 projects from the upper surface of the interlayer insulating film 11. Thus, a projecting step 14a is formed. The lower electrode layer 15, the fixed layer 16 and the tunnel insulating film 17 stacked on the step 14a are shaped to project along the shape of the step 14a. Specifically, the bottom surface of the lower electrode layer 15 is recessed along the shape of the step 14a, and the upper surface of the lower electrode layer 15 projects in accordance with the recession of the bottom surface. The bottom surface of the fixed layer 16 is recessed along the projecting shape of the upper surface of the lower electrode layer 15, and the upper surface of the fixed layer 16 projects in accordance with the recession of the bottom surface. The bottom surface of the tunnel insulating film 17 is recessed along the projecting shape of the upper surface of the fixed layer 16, and the upper surface of the tunnel insulating film 17 projects in accordance with the recession of the bottom surface. As a result, the bottom surface of the recording layer 18 has a recessed portion, and the tunnel insulating film 17 and the fixed layer 16 are put in this recessed portion.

The recording layer 18 is formed over the step 14a. The area of the planar shape of the recording layer 18 is greater than the area of the planar shape of the contact plug 13 and smaller than the area of the planar shape of the lower electrode layer 15, the fixed layer 16 and the tunnel insulating film 17 (see FIG. 1B). The lower electrode layer 15, the fixed layer 16 and the tunnel insulating film 17 have the same planar shape, and the side surfaces of the lower electrode layer 15, the fixed layer 16 and the tunnel insulating film 17 correspond to one another.

The center of the insulating gap layer 19 covers the recording layer 18, and the end of the insulating gap layer 19 is in direct contact with the tunnel insulating film 17. The conducting gap layer 20 is formed on the insulating gap layer 19. The insulating gap layer 19 and the conducting gap layer 20 have the same planar shape, and the side surfaces of the insulating gap layer 19 and the conducting gap layer 20 correspond to each other. The area of the planar shape of the insulating gap layer 19 and the conducting gap layer 20 is smaller than the area of the planar shape of the lower electrode layer 15, the fixed layer 16 and the tunnel insulating film 17 and greater than the area of the planar shape of the recording layer 18.

The recording layer 18 is electrically connected to the bit line 23 via the insulating gap layer 19 and the conducting gap layer 20. Here, the insulating gap layer 19 is an insulating layer. However, the insulating gap layer 19 is extremely thin and has sufficiently low tunnel resistance, and is approximately regarded as a conductor. Therefore, the insulating gap layer 19 hardly has an adverse effect on the electric connection between the recording layer 18 and the bit line 23.

The thickness of the tunnel insulating film 17 formed between the recording layer 18 and the fixed layer 16 is smaller than the total thickness of the insulating gap layer 19 and the tunnel insulating film 17 formed between the conducting gap layer 20 and the fixed layer 16. As a result, a current running through the end of the MTJ element MTJ is negligibly smaller than a current running through the center of the MTJ element MTJ, so that a magnetoresistance (MR) ratio in reading operation can be stabilized.

The material of the insulating gap layer 19 is desirably the same as the material of the tunnel insulating film 17, but may be a different material. The insulating gap layer 19 and the tunnel insulating film 17 are desirably made of a material whose resistance is exponentially proportional to the thickness of the insulating film. The resistance area products (RA) [Ω·μm²] between the fixed layer 16 and the recording layer 18 can be desirably controlled to be a value less than or equal to at least a one-hundredth of the RA between the fixed layer 16 and the conducting gap layer 20.

[1-2] Manufacturing Method

FIGS. 2A and 2B to 5A and 5B are sectional views showing the process of manufacturing the magnetic random access memory according to the first embodiment of the present invention. A method of manufacturing the magnetic random access memory according to the first embodiment is described below.

First, as shown in FIGS. 2A and 2B, a switching element and a multilevel interconnection (not shown) are formed on a semiconductor substrate (not shown). Further, a contact hole 12 is formed in an interlayer insulating film 11, and a metal material is formed in the contact hole 12 and on the interlayer insulating film 11. Further, the metal material is planarized by, for example, chemical mechanical polishing (CMP), and a contact plug 13 to be electrically connected to the switching element is formed. In this case, the etching rate of the interlayer insulating film 11 is controlled so that it is higher than the etching rate of the metal material of the contact plug 13. Thus, the upper surface of the contact plug 13 projects about several tens of nanometers from the upper surface of the interlayer insulating film 11. As a result, a projecting step 14a is formed. In addition, this step of several tens of nanometers may be formed by simply etching back an oxide film using the same lithography mask as that for an MTJ pattern.

Then, a lower electrode layer 15 is formed on the contact plug 13 and the interlayer insulating film 11, and an MTJ material layer is formed on the lower electrode layer 15. Specifically, the lower electrode layer 15 and a fixed layer 16 having a thickness of 10 nm are formed on the contact plug 13 and the interlayer insulating film 11, and a tunnel insulating film 17 having a thickness of about 1 nm is formed on the fixed layer 16, and then a recording layer 18 having a thickness of about 1 nm is formed on the tunnel insulating film 17.

Then, as shown in FIGS. 3A and 3B, annealing at, for example, about 500° C. is performed. Thus, the recording layer 18 having a thickness of about several nanometers is agglomerated. At this point, the step 14a is present in the foundation of the recording layer 18 so that agglomerated particles of the recording layer 18 are formed in a region including the step 14a. In addition, the agglomerated particles of the recording layer 18 are also randomly formed in parts other than the part corresponding to the step 14a of the contact plug 13. The degree of this agglomeration can be controlled by the thickness of the recording layer 18, annealing temperature or atmosphere.

Then, as shown in FIGS. 4A and 4B, an insulating gap layer 19 having a thickness of about 1 nm or less is deposited on the agglomerated particles of the recording layer 18 and the tunnel insulating film 17, and a conducting gap layer 20 having a thickness of about 10 nm is deposited on the insulating gap layer 19. Further, a resist pattern 21 for MTJ fabrication is formed on the conducting gap layer 20 by a normal photolithographic step.

Then, as shown in FIGS. 5A and 5B, after an etching step of, for example, normal reactive ion etching (RIE), the resist pattern 21 is transferred to the conducting gap layer 20. Using this conducting gap layer 20 as a mask, the insulating gap layer 19 and the agglomerated particles of the recording layer 18 formed in parts other than a region above the contact plug 13 are etched and removed by a method such as ion trimming. Subsequently, the resist pattern 21 is removed.

Then, as shown in FIGS. 1A and 1B, the tunnel insulating film 17, the fixed layer 16 and the lower electrode layer 15 are electrically separated bit by bit into desired patterns for lower electrodes by normal photolithography and an etching technique. Further, an interlayer insulating film 22 is deposited all over the surface and planarized, so that the conducting gap layer 20 is partly exposed. A bit line 23 is formed in electric contact with the conducting gap layer 20. This bit line 23 has a stacked structure composed of, for example, a barrier metal, a low resistant material and a barrier metal. Further, the bit line 23 is processed by normal lithographic and etching steps, such that a memory cell is completed.

In addition, the present embodiment is as shown in FIGS. 6A and 6B when an insulating hard mask layer 30 is used instead of the conducting gap layer 20. In this case, when the interlayer insulating film 22 formed after the fabrication of an MTJ element MTJ is etched back, the insulating hard mask layer 30 is also etched back so that the insulating gap layer 19 or the recording layer 18 under the insulating hard mask layer 30 is partly exposed. Moreover, the exposed part of the insulating gap layer 19 or the recording layer 18 is formed to be in electric contact with the bit line 23. In the case in FIGS. 6A and 6B, the insulating gap layer 19 and the insulating hard mask layer 30 have different functions, and the insulating gap layer 19 can therefore be omitted. Furthermore, in the present embodiment, the tunnel insulating film 17, the fixed layer 16, the lower electrode layer 15, the insulating gap layer 19 and the conducting gap layer 20 can also be formed by collective fabrication.

[1-3] Effects

According to the first embodiment described above, the projecting step 14a is provided in the foundation of the MTJ element MTJ, so that the agglomerated particles gather in this projecting step 14a when the recording layer 18 is agglomerated by a thermal treatment. Thus, the recording layers 18 separated cell by cell can be formed. Using such a method, the MTJ elements MTJ having micro and high crystallinity beyond the limit of a normal photolithographic technique can be formed with good controllability in a region where the MTJ elements MTJ should be formed bit by bit. Consequently, it is possible to provide an MTJ element MTJ for an MRAM cell capable of more stable writing with a low current.

### [2] Second Embodiment

While the step under the MTJ element has a projecting shape in the first embodiment described above, a step under an MTJ element has a recessed shape in the second embodiment. It is to be noted that parts in the second embodiment similar to the parts in the first embodiment are not described.

[2-1] Structure

FIGS. 7A and 7B are a sectional view and a planar view showing a magnetic random access memory according to the second embodiment of the present invention. The structure of the magnetic random access memory according to the second embodiment is described below.

As shown in FIGS. 7A and 7B, the first embodiment is different from the second embodiment in that the upper surface of a contact plug 13 is recessed as compared with the upper surface of an interlayer insulating film 11 and that a recessed step 14b is formed.

Specifically, the bottom surface of a lower electrode layer 15 projects along the shape of the step 14b, and the upper surface of the lower electrode layer 15 is recessed in accordance with the projection of the bottom surface. The bottom surface of a fixed layer 16 projects along the recessed shape of the upper surface of the lower electrode layer 15, and the upper surface of the fixed layer 16 is recessed in accordance with the projection of the bottom surface. The bottom surface of a tunnel insulating film 17 projects along the recessed shape of the upper surface of the fixed layer 16, and the upper surface of the tunnel insulating film 17 is recessed in accordance with the projection of the bottom surface. As a result, the bottom surface of a recording layer 18 has a projecting portion, and this projecting portion is put in the upper part of the tunnel insulating film 17.

[2-2] Manufacturing Method

FIGS. 8A and 8B to 11A and 11B are sectional views and planar views showing the process of manufacturing the magnetic random access memory according to the second embodiment of the present invention. A method of manufacturing the magnetic random access memory according to the second embodiment is described below.

First, as shown in FIGS. 8A and 8B, a contact hole 12 is formed in an interlayer insulating film 11, and a metal material is formed in the contact hole 12 and on the interlayer insulating film 11, as in the first embodiment. Further, the metal material is planarized by, for example, the CMP, and a contact plug 13 to be electrically connected to a switching element is formed. In this case, in the second embodiment, the etching rate of the metal material of the contact plug 13 is controlled so that it is higher than the etching rate of the interlayer insulating film 11. Thus, the upper surface of the contact plug 13 is recessed about several tens of nanometers from the upper surface of the interlayer insulating film 11. As a result, a recessed step 14b is formed. Subsequently, a lower electrode layer 15, a fixed layer 16, a tunnel insulating film 17 and a recording layer 18 are stacked in order on the contact plug 13 and the interlayer insulating film 11.

Then, as shown in FIGS. 9A and 9B, annealing at, for example, about 500° C. is performed. Thus, the recording layer 18 having a thickness of about several nanometers is agglomerated. At this point, the step 14b is present in the foundation of the recording layer 18 so that agglomerated particles of the recording layer 18 are formed in a region including the step 14b. In addition, the agglomerated particles of the recording layer 18 are also randomly formed in parts other than the part corresponding to the step 14b of the contact plug 13.

Subsequently, in the process similar to that in the first embodiment, a memory cell as shown in FIGS. 7A and 7B is completed after steps in FIGS. 10A and 10B and FIGS. 11A and 11B.

In addition, the present embodiment is as shown in FIGS. 12A and 12B when an insulating hard mask layer 30 is used instead of a conducting gap layer 20. Details of this structure are similar to the details of the corresponding structure in the first embodiment.

[2-3] Effects

According to the second embodiment described above, the recessed step 14b is provided in the foundation of the MTJ element MTJ, so that the agglomerated particles gather in this projecting step 14b when the recording layer 18 is agglomerated. Thus, effects similar to the effects in the first embodiment can be obtained.

### [3] Third Embodiment

In the third embodiment, a projecting step is formed as in the first embodiment. However, in contrast with the first embodiment, a contact plug is greater than a recording layer so that a step is greater in the third embodiment. It is to be noted that parts in the third embodiment similar to the parts in the first embodiment are not described.

[3-1] Structure

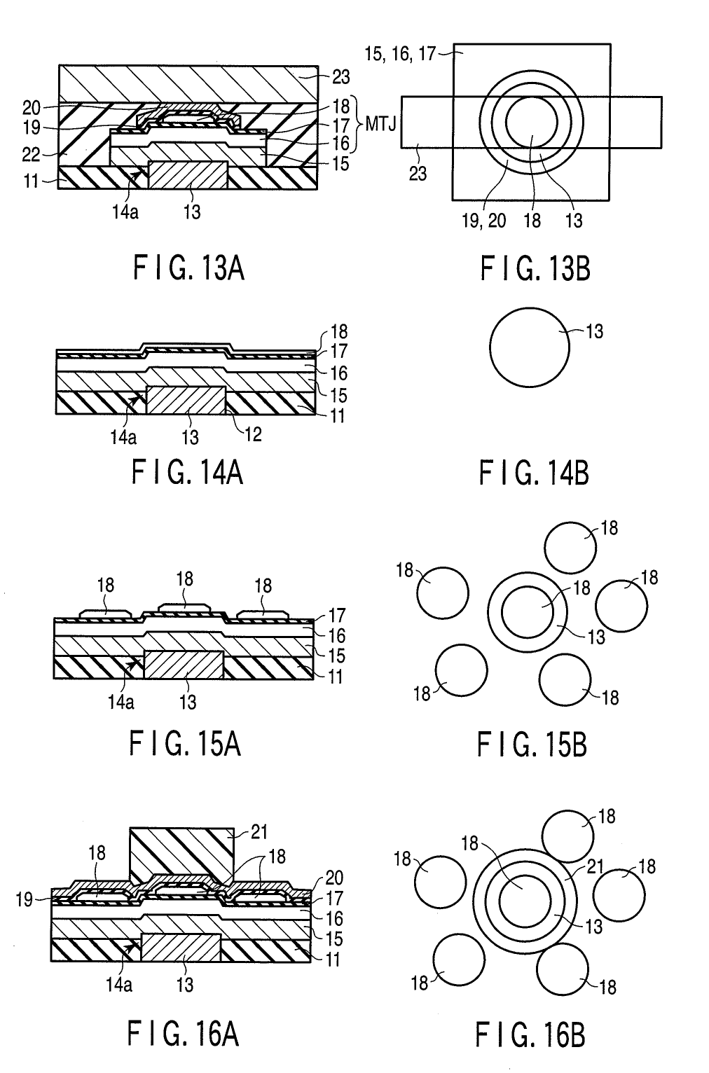

FIGS. 13A and 13B are a sectional view and a planar view showing a magnetic random access memory according to the third embodiment of the present invention. The structure of the magnetic random access memory according to the third embodiment is described below.

As shown in FIGS. 13A and 13B, the third embodiment is different from the first embodiment in that the area of the planar shape of a recording layer 18 is smaller than the area of the planar shape of a contact plug 13 and that the recording layer 18 is formed inside a step 14a.

Specifically, the bottom surface of a lower electrode layer 15 is recessed along the shape of the step 14a, and the upper surface of the lower electrode layer 15 projects in accordance with the recession of the bottom surface. The bottom surface of a fixed layer 16 is recessed along the projecting shape of the upper surface of the lower electrode layer 15, and the upper surface of the fixed layer 16 projects in accordance with the recession of the bottom surface. The bottom surface of a tunnel insulating film 17 is recessed along the projecting shape of the upper surface of the fixed layer 16, and the upper surface of the tunnel insulating film 17 projects in accordance with the recession of the bottom surface. The area of the projecting planar shape of the tunnel insulating film 17 is great in accordance with the area of the contact plug 13, and the recording layer 18 is formed on the planar upper surface of the tunnel insulating film 17. Therefore, the bottom surface of the recording layer 18 is planar.

[3-2] Manufacturing Method

FIGS. 14A and 14B to 17A and 17B are sectional views and planar views showing the process of manufacturing the magnetic random access memory according to the third embodiment of the present invention. A method of manufacturing the magnetic random access memory according to the third embodiment is described below.

First, as shown in FIGS. 14A and 14B, a contact hole 12 is formed in an interlayer insulating film 11. The contact hole 12 formed in this case is greater than the contact hole 12 in the first embodiment. Further, a contact plug 13 is formed in the contact hole 12. At this point, the upper surface of the contact plug 13 projects about several tens of nanometers from the upper surface of the interlayer insulating film 11, and a projecting step 14a is formed in the interlayer insulating film 11. Subsequently, a lower electrode layer 15, a fixed layer 16, a tunnel insulating film 17 and a recording layer 18 are stacked in order on the contact plug 13 and the interlayer insulating film 11.

Then, as shown in FIGS. 15A and 15B, annealing at, for example, about 500° C. is performed. Thus, the recording layer 18 having a thickness of about several nanometers is agglomerated. At this point, the step 14a is present in the foundation of the recording layer 18, and particles are thus agglomerated in such a manner as to be separated by the step 14a. As a result, micro agglomerated particles of the recording layer 18 are formed. In addition, the agglomerated particles of the recording layer 18 are also randomly formed in parts other than the part corresponding to the step 14a of the contact plug 13.

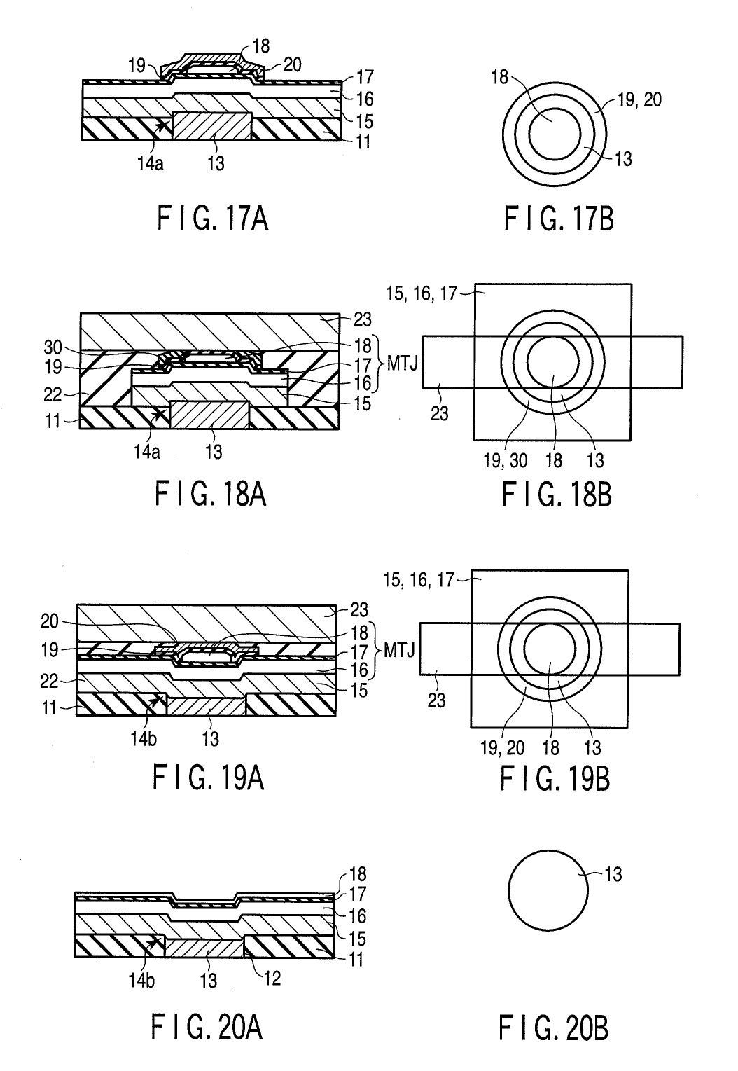

Subsequently, in the process similar to that in the first embodiment, a memory cell as shown in FIGS. 13A and 13B is completed after steps in FIGS. 16A and 16B and FIGS. 17A and 17B.

In addition, the present embodiment is as shown in FIGS. 18A and 18B when an insulating hard mask layer 30 is used instead of a conducting gap layer 20. Details of this structure are similar to the details of the corresponding structure in the first embodiment.

[3-3] Effects

According to the third embodiment described above, effects similar to the effects in the first embodiment can be obtained. Moreover, the step 14a greater than the step 14a in the first embodiment is formed, so that the agglomerated particles of the recording layer 18 can be formed with further enhanced controllability. This enables a more stable process, improved yield and reduced costs.

### [4] Fourth Embodiment

In the fourth embodiment, a recessed step is formed as in the second embodiment. However, in contrast with the second embodiment, a contact plug is greater than a recording layer so that a step is greater in the fourth embodiment. It is to be noted that parts in the fourth embodiment similar to the parts in the first and second embodiments are not described.

[4-1] Structure

FIGS. 19A and 19B are a sectional view and a planar view showing a magnetic random access memory according to the fourth embodiment of the present invention. The structure of the magnetic random access memory according to the fourth embodiment is described below.

As shown in FIGS. 19A and 19B, the fourth embodiment is different from the second embodiment in that the area of the planar shape of a recording layer 18 is smaller than the area of the planar shape of a contact plug 13 and that the recording layer 18 is formed inside a step 14b.

Specifically, the bottom surface of a lower electrode layer 15 projects along the shape of the step 14b, and the upper surface of the lower electrode layer 15 is recessed in accordance with the projection of the bottom surface. The bottom surface of a fixed layer 16 projects along the recessed shape of the upper surface of the lower electrode layer 15, and the upper surface of the fixed layer 16 is recessed in accordance with the projection of the bottom surface. The bottom surface of a tunnel insulating film 17 projects along the recessed shape of the upper surface of the fixed layer 16, and the upper surface of the tunnel insulating film 17 is recessed in accordance with the projection of the bottom surface. The area of the recessed planar shape of the tunnel insulating film 17 is great in accordance with the area of the contact plug 13, and the recording layer 18 is formed on the planar upper surface of the tunnel insulating film 17. Therefore, the bottom surface of the recording layer 18 is planar.

[4-2] Manufacturing Method

FIGS. 20A and 20B to 23A and 23B are sectional views and planar views showing the process of manufacturing the magnetic random access memory according to the fourth embodiment of the present invention. A method of manufacturing the magnetic random access memory according to the fourth embodiment is described below.

First, as shown in FIGS. 20A and 20B, a contact hole 12 is formed in an interlayer insulating film 11. The contact hole 12 formed in this case is greater than the contact hole 12 in the second embodiment. Further, a contact plug 13 is formed in the contact hole 12. At this point, the upper surface of the contact plug 13 is recessed about several tens of nanometers from the upper surface of the interlayer insulating film 11, and a recessed step 14b is formed in the interlayer insulating film 11. Subsequently, a lower electrode layer 15, a fixed layer 16, a tunnel insulating film 17 and a recording layer 18 are stacked in order on the contact plug 13 and the interlayer insulating film 11.

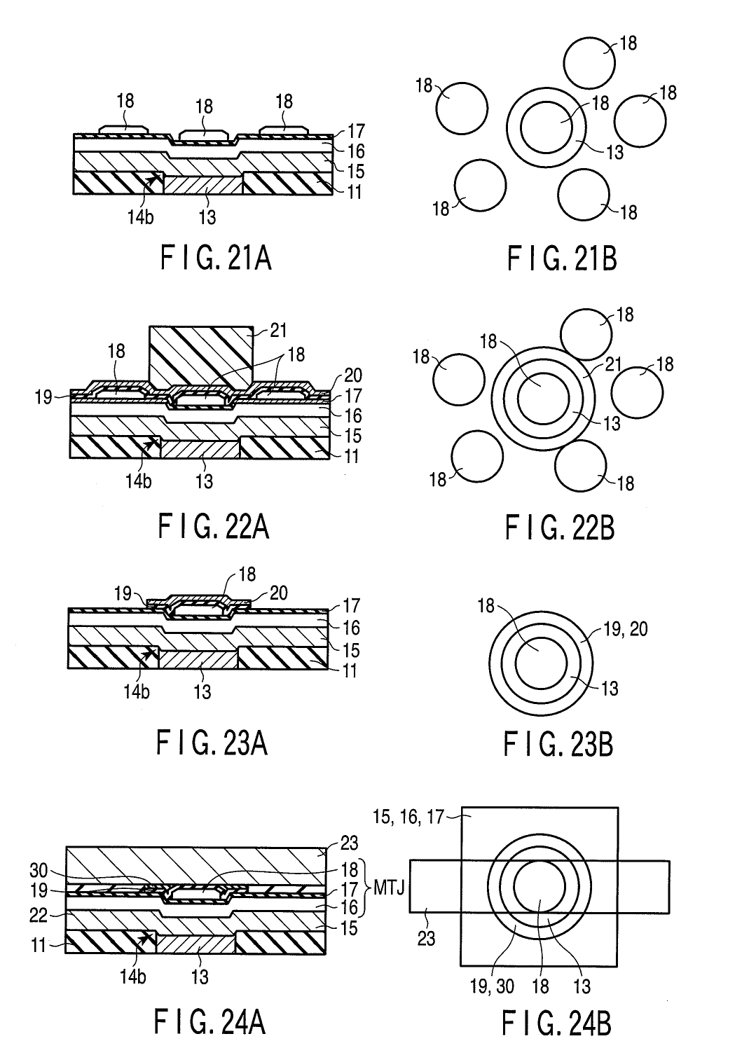

Then, as shown in FIGS. 21A and 21B, annealing at, for example, about 500° C. is performed. Thus, the recording layer 18 having a thickness of about several tens of nanometers is agglomerated. At this point, the step 14b is present in the foundation of the recording layer 18, and particles are thus agglomerated in such a manner as to be separated by the step 14b. As a result, micro agglomerated particles of the recording layer 18 are formed. In addition, the agglomerated particles of the recording layer 18 are also randomly formed in parts other than the part corresponding to the step 14a of the contact plug 13.

Subsequently, in the process similar to that in the first embodiment, a memory cell as shown in FIGS. 19A and 19B is completed after steps in FIGS. 22A and 22B and FIGS. 23A and 23B.

In addition, the present embodiment is as shown in FIGS. 24A and 24B when an insulating hard mask layer 30 is used instead of a conducting gap layer 20. Details of this structure are similar to the details of the corresponding structure in the first embodiment.

[4-3] Effects

According to the fourth embodiment described above, effects similar to the effects in the second embodiment can be obtained. Moreover, the step 14a greater than the step 14a in the second embodiment is formed, so that the agglomerated particles of the recording layer 18 can be formed with further enhanced controllability. This enables a more stable process, improved yield and reduced costs.

### [5] Fifth Embodiment

While the bottom pin structure in which the fixed layer is formed below the recording layer is used in the first to fourth embodiments described above, a top pin structure in which a fixed layer is formed above a recording layer is used in the fifth embodiment. In the example shown in the fifth embodiment, a projecting portion is formed, and a contact plug is greater than a recording layer, as in the third embodiment. However, the fifth embodiment can be changed to be similar to the first and second embodiments. Here, parts similar to the parts in the previously described embodiments are not described.

[5-1] Structure

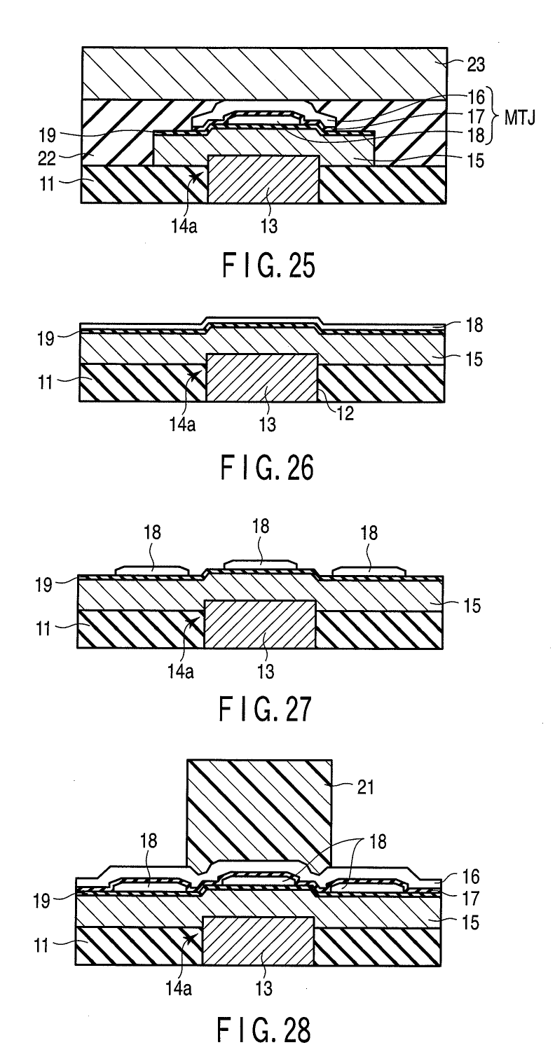

FIG. 25 is a sectional view showing a magnetic random access memory according to a fifth embodiment of the present invention. The magnetic random access memory according to the fifth embodiment is described below.

As shown in FIG. 25, the fifth embodiment is different from the third embodiment in that a fixed layer 16 is located closer to a bit line 23 than a recording layer 18.

Specifically, a lower electrode layer 15 is formed on a contact plug 13 and an interlayer insulating film 11, and an insulating gap layer 19 is formed on the lower electrode layer 15. The recording layer 18 is formed on the insulating gap layer 19, and a tunnel insulating film 17 is formed over the recording layer 18. The fixed layer 16 is formed on the tunnel insulating film 17, and the bit line 23 is formed on the fixed layer 16.

The upper surface of the contact plug 13 projects from the upper surface of the interlayer insulating film 11, so that a projecting step 14a is formed. The bottom surface of the lower electrode layer 15 is recessed along the shape of the step 14a, and the upper surface of the lower electrode layer 15 projects in accordance with the recession of the bottom surface. The bottom surface of the insulating gap layer 19 is recessed along the projecting shape of the upper surface of the lower electrode layer 15, and the upper surface of the insulating gap layer 19 projects in accordance with the recession of the bottom surface. The area of the projecting planar shape of the insulating gap layer 19 is great in accordance with the area of the contact plug 13, and the recording layer 18 is formed on the planar upper surface of the insulating gap layer 19. Therefore, the bottom surface of the recording layer 18 is planar.

The area of the planar shape of the recording layer 18 is smaller than the area of the planar shape of the contact plug 13. The area of the planar shape of the contact plug 13 is smaller than the area of the planar shape of the fixed layer 16 and the tunnel insulating film 17. The area of the planar shape of the fixed layer 16 and the tunnel insulating film 17 is smaller than the area of the lower electrode layer 15 and the insulating gap layer 19.

The lower electrode layer 15 and the insulating gap layer 19 have the same planar shape, and the side surfaces of the lower electrode layer 15 and the insulating gap layer 19 correspond to each other. The fixed layer 16 and the tunnel insulating film 17 have the same planar shape, and the side surfaces of the fixed layer 16 and the tunnel insulating film 17 correspond to each other.

The center of the tunnel insulating film 17 covers the recording layer 18, and the end of the tunnel insulating film 17 is in direct contact with the insulating gap layer 19. The thickness of the tunnel insulating film 17 formed between the recording layer 18 and the fixed layer 16 is smaller than the total thickness of the insulating gap layer 19 and the tunnel insulating film 17 formed between the lower electrode layer 15 and the fixed layer 16. As a result, a current running through the end of an MTJ element MTJ is negligibly smaller than a current running through the center of the MTJ element MTJ, so that an MR ratio in reading operation can be stabilized.

[5-2] Manufacturing Method

FIGS. 26 to 29 are sectional views showing the process of manufacturing the magnetic random access memory according to the fifth embodiment of the present invention. A method of manufacturing the magnetic random access memory according to the fifth embodiment is described below.

First, as shown in FIG. 26, a contact hole 12 is formed in an interlayer insulating film 11. The contact hole 12 formed in this case is greater than the contact hole 12 in the first embodiment. Further, a contact plug 13 is formed in the contact hole 12. At this point, the upper surface of the contact plug 13 projects about several tens of nanometers from the upper surface of the interlayer insulating film 11, and a projecting step 14b is formed in the interlayer insulating film 11. In addition, this step of several tens of nanometers may be formed by simply etching back an oxide film using the same lithography mask as that for an MTJ pattern. Subsequently, a lower electrode layer 15, an insulating gap layer 19 and a recording layer 18 are stacked in order on the contact plug 13 and the interlayer insulating film 11.

Then, as shown in FIG. 27, annealing at, for example, about 500° C. is performed. Thus, the recording layer 18 having a thickness of about several tens of nanometers is agglomerated. At this point, a step 14a is present in the foundation of the recording layer 18, and particles are thus agglomerated in such a manner as to be separated by the step 14a. As a result, micro agglomerated particles of the recording layer 18 are formed. In addition, the agglomerated particles of the recording layer 18 are also randomly formed in parts other than the part corresponding to the step 14a of the contact plug 13.

Then, as shown in FIG. 28, a tunnel insulating film 17 and a fixed layer 16 are stacked in order on the recording layer 18 and the insulating gap layer 19. Further, a resist pattern 21 for MTJ fabrication is formed on the fixed layer 16 by a normal photolithographic step.

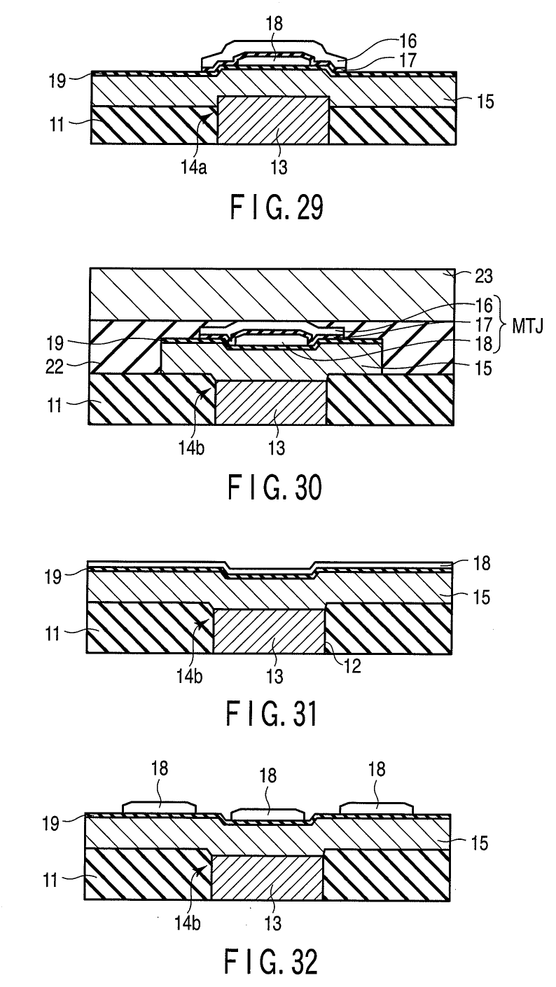

Then, as shown in FIG. 29, after an etching step of, for example, normal RIE, the resist pattern 21 is used as a mask to process the fixed layer 16 and tunnel insulating film 17 by a method such as ion trimming. At this point, the agglomerated particles of the recording layer 18 formed in parts other than a region above the contact plug 13 are etched and removed. Subsequently, the resist pattern 21 is removed.

Then, as shown in FIG. 25, the lower electrode layer 15 and the insulating gap layer 19 are separated by the normal photolithography and the etching technique. Further, an interlayer insulating film 22 is deposited all over the surface and planarized, so that the fixed layer 16 is partly exposed. A bit line 23 is formed in electric contact with the fixed layer 16. This bit line 23 has a stacked structure composed of, for example, a barrier metal, a low resistant material and a barrier metal. Further, the bit line 23 is processed by normal lithographic and etching steps, such that a memory cell is completed.

In addition, the fixed layer 16 in the present embodiment may be composed of a fixed layer and an upper electrode layer formed on this fixed layer.

Furthermore, in the present embodiment, the tunnel insulating film 17, the fixed layer 16, the lower electrode layer 15 and the insulating gap layer 19 can also be formed by collective fabrication.

[5-3] Effects

According to the fifth embodiment described above, effects similar to the effects in the first and third embodiments can be obtained.

Moreover, the fifth embodiment uses the top pin structure in which the fixed layer 16 is formed above the recording layer 18. Therefore, the fixed layer 16 and the tunnel insulating film 17 are not present during the formation and particle forming process of the recording layer 18, so that it is possible to select a process including a thermal step suitable for the crystallization and performance enhancement of the recording layer 18. Consequently, it is possible to provide an MTJ element MTJ for an MRAM cell capable of more stable writing with a low current.

### [6] Sixth Embodiment

While the step under the MTJ element has a projecting shape in the fifth embodiment described above, the step under the MTJ element has a recessed shape in the sixth embodiment. It is to be noted that parts in the sixth embodiment similar to the parts in the fifth embodiment are not described.

[6-1] Structure

FIG. 30 is a sectional view showing a magnetic random access memory according to the sixth embodiment of the present invention. The magnetic random access memory according to the sixth embodiment is described below.

As shown in FIG. 30, the sixth embodiment is different from the fifth embodiment in that the upper surface of a contact plug 13 is recessed as compared with the upper surface of an interlayer insulating film 11 and that a recessed step 14b is formed.

Specifically, the bottom surface of a lower electrode layer 15 projects along the shape of the step 14b, and the upper surface of the lower electrode layer 15 is recessed in accordance with the projection of the bottom surface. The bottom surface of an insulating gap layer 19 projects along the recessed shape of the upper surface of the lower electrode layer 15, and the upper surface of the insulating gap layer 19 is recessed in accordance with the projection of the bottom surface. The area of the recessed planar shape of the insulating gap layer 19 is great in accordance with the area of the contact plug 13, and a recording layer 18 is formed on the planar upper surface of the insulating gap layer 19. Therefore, the bottom surface of the recording layer 18 is planar.

[6-2] Manufacturing Method

FIGS. 31 to 34 are sectional views showing the process of manufacturing the magnetic random access memory according to the sixth embodiment of the present invention. A method of manufacturing the magnetic random access memory according to the sixth embodiment is described below.

First, as shown in FIG. 31, a contact hole 12 is formed in an interlayer insulating film 11, and a metal material is formed in the contact hole 12 and on the interlayer insulating film 11, as in the first embodiment. Further, the metal material is planarized by, for example, the CMP, and a contact plug 13 to be electrically connected to a switching element is formed. In this case, in the sixth embodiment, the etching rate of the metal material of the contact plug 13 is controlled so that it is higher than the etching rate of the interlayer insulating film 11. Thus, the upper surface of the contact plug 13 is recessed about several tens of nanometers from the upper surface of the interlayer insulating film 11. As a result, a recessed step 14b is formed. Subsequently, a lower electrode layer 15, an insulating gap layer 19 and a recording layer 18 are stacked in order on the contact plug 13 and the interlayer insulating film 11.

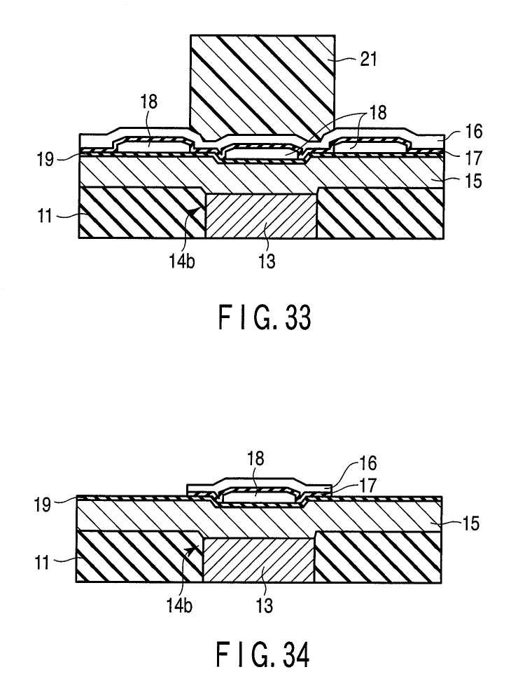

Then, as shown in FIG. 32, annealing at, for example, about 500° C. is performed. Thus, the recording layer 18 having a thickness of about several tens of nanometers is agglomerated. At this point, a step 14b is present in the foundation of the recording layer 18, and micro agglomerated particles of the recording layer 18 are formed in a region within the step 14b. In addition, the agglomerated particles of the recording layer 18 are also randomly formed in parts other than the part corresponding to the step 14b of the contact plug 13. Subsequently, in the process similar to that in the fifth embodiment, a memory cell as shown in FIG. 30 is completed after steps in FIG. 33 and FIG. 34.

[6-3] Effects

According to the sixth embodiment described above, the recessed step 14b is provided in the foundation of the MTJ element MTJ, so that the agglomerated particles gather in this projecting step 14b when the recording layer 18 is agglomerated. Thus, effects similar to the effects in the fifth embodiment can be obtained.

[7] Memory Cell

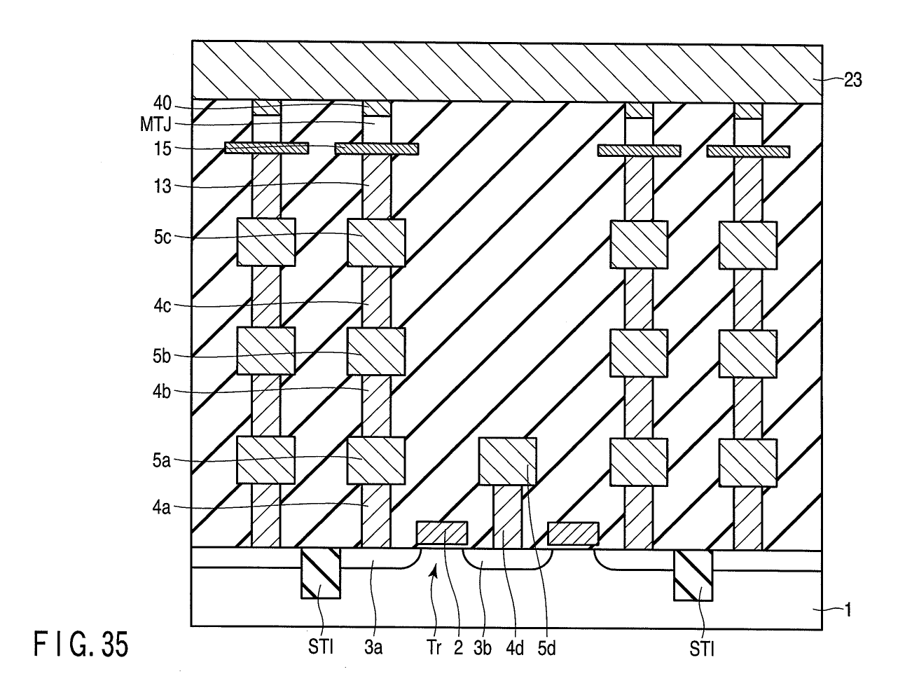

The structure of the memory cell in the magnetic random access memory according to each of the embodiments of the present invention is described with FIG. 35.

As shown in FIG. 35, a transistor Tr serving as a switching element is formed in a semiconductor substrate 1. This transistor Tr has a gate electrode 2 formed on the semiconductor substrate 1 via a gate insulating film (not shown), and source/drain diffusion layers 3a, 3b formed in the semiconductor substrate 1 on both sides of the gate electrode 2. The MTJ element MTJ is connected to the source/drain diffusion layer 3a via contacts 4a, 4b, 4c, 13, interconnects 5a, 5b, 5c and the lower electrode layer 15. The MTJ element MTJ is connected to the bit line 23 via an upper layer 40. Here, the upper layer 40 corresponds to, for example, the insulating gap layer 19 and the conducting gap layer 20 or to the insulating gap layer 19 and the insulating hard mask layer 30 in the first to fourth embodiments. An interconnect 5d is connected to the source/drain diffusion layer 3b via a contact 4d.

Although parts corresponding to the contact 13, the lower electrode layer 15, the MTJ element MTJ and the upper layer 40 are schematically shown in FIG. 35, the structures in the embodiments described above are applied to these parts.

[8] Material of MTJ Element

The MTJ element according to the embodiments described above is made of the following materials.

[8-1] In-plane Magnetization Type

An in-plane-magnetization MTJ element of a single tunnel junction structure or a double tunnel junction structure is formed using, for example, the following materials.

As the materials of the fixed layer 16 and the recording layer 18, it is preferable to use, for example, Fe, Co, Ni or an alloy of these substances, magnetite having high spin polarizability, and an oxide such as CrO₂ or RXMnO_{3-y} (R; rare earth, X; Ca, Ba, Sr) as well as a Heusler alloy such as NiMnSb or PtMnSb. As long as ferromagnetism is not lost, these magnetic materials may contain a slight amount of nonmagnetic elements such as Ag, Cu, Au, Al, Mg, Si, Bi, Ta, B, C, O, N, Pd, Pt, Zr, Ir, W, Mo and Nb.

As the material of an antiferromagnetic layer forming part of the fixed layer 16, it is preferable to use, for example, Fe—Mn, Pt—Mn, Pt—Cr—Mn, Ni—Mn, Ir—Mn, NiO or Fe₂O₃.

As the material of the tunnel insulating film 17, it is desirable to use a tunnel barrier which is formed by, for example, stacking and annealing magnesium oxide (MgO) or magnesium (Mg) having a coherent tunneling effect as a spin injection MTJ element and magnesium oxide (MgO). Instead of these materials, it is possible to use various dielectric materials such as Al₂O₃, SiO₂, AlN, Bi₂O₃, MgF₂, CaF₂, SrTiO₂ and AlLaO₃. These dielectric materials may have oxygen, nitrogen and fluorine deficiency.

[8-2] Perpendicular Magnetization Type

The tunnel insulating film 17 is the same as an in-plane-magnetization magnetic tunnel junction.

[A] A magnetic material having great coercive force is made of a material having a high magnetic anisotropy energy density of 1×10⁶ erg/cc or more.

Examples of these materials are described below.

### (1) Example 1

### A material Made of an Alloy Containing at least One of Iron (Fe), Cobalt (Co) and Nickel (Ni) and at Least One of Chromium (Cr), Platinum (Pt) and Palladium (Pd)

An ordered alloy includes, for example, Fe(50)Pt(50), Fe(50)Pd(50) or Co(50)Pt(50). A disordered alloy includes, for example, a CoCr alloy, a CoPt alloy, a CoCrPt alloy, a CoCrPtTa alloy or a CoCrNb alloy.

### (2) Example 2

### A Material having an Alternatively Stacked Structure of at Least One of Fe, Co and Ni or an Alloy Containing One of These Substances and One of Pd and Pt or an Alloy Containing One of These Substances

This material includes, for example, Co/Pt artificial lattice, Co/Pd artificial lattice and CoCr/Pt artificial lattice. In the case of using the Co/Pt artificial lattice and the case of using the Co/Pd artificial lattice, it is possible to attain a high value of about 40% in resistance change rate (MR ratio).

### Example 3

### An Amorphous Alloy Made of at Least One of Rare Earth Metals Such as Terbium (Tb), Dysprosium (Dy) or Gadolinium (Gd) and at Least One of Transition Metals

This material includes, for example, TbFe, TbCo, TbFeCo, DyTbFeCo and GdTbCo.

[B] The recording layer 18 can be made of the above-mentioned magnetic material having great coercive force, or may also be made of a magnetic material having a magnetic anisotropy energy density lower than that of the above-mentioned magnetic material having great coercive force after the adjustment of the composition ratio, the addition of an impurity and the adjustment of the thickness.

Examples of such a material are described below.

### (1) Example 1

### A Material in which an Impurity is Added to an Alloy Containing at Least One of Fe, Co and Ni and at Least One of Cr, Pt and Pd

An ordered alloy includes, for example, an alloy in which an impurity such as Cu, Cr or Ag is added to Fe(50)Pt(50), Fe(50)Pd(50) or Co(50)Pt(50) to decrease the magnetic anisotropy energy density. A disordered alloy includes, for example, a CoCr alloy, a CoPt alloy, a CoCrPt alloy, a CoCrPtTa alloy or a CoCrNb alloy in which the ratio of a nonmagnetic element is increased to decrease the magnetic anisotropy energy density.

### (2) Example 2

### A Material Having an Alternately Stacked Structure Of at Least One of Fe, Co and Ni or an Alloy Containing One of these Substances and One of Pd and Pt or an Alloy Containing One of these Substances, the Thickness of a Layer Made of the Former Element or Alloy or the Thickness of a Layer Made of the Latter Element or Alloy Having been Adjusted

There are an optimum value of the thickness of at least one of Fe, Co and Ni or an alloy containing one of these substances and an optimum value of the thickness of one of Pd and Pt or an alloy containing one of these substances. As the thickness departs from these optimum values, the magnetic anisotropy energy density gradually decreases.

### (3) Example 3

### An Amorphous Alloy Made of at Least One of Rare Earth Metals Such as Terbium (Tb), Dysprosium (Dy) or Gadolinium (Gd) and at Least One of Transition Metals, Which Composition Ratio has been Adjusted

This material includes an amorphous alloy such as TbFe, TbCo, TbFeCo, DyTbFeCo or GdTbCo in which the composition ratio has been adjusted to decrease the magnetic anisotropy energy density.

When, for example, Co/Pt artificial lattice is used as the recording layer 18, the thickness of Co and Pt can be adjusted to adjust the coercive force of the MTJ element.

When, for example, an ordered alloy such as FePt or CoPt is used as the fixed layer 16, it is necessary to orient an fct (001) face in order to generate perpendicular magnetic anisotropy. Therefore, an extremely thin foundation layer having a thickness of about several tens of nanometers and made of MgO is preferably used as a crystal orientation control layer. Instead of MgO, it is possible to use an element or compound, such as Pt, Pd, Ag, Au, Al, Cu, Cr, or Fe, having an fcc structure or bcc structure with a lattice constant of about 0.28, 0.40 or 0.56 nm, or an alloy of these substances. In the case of the bottom pin structure, the crystal orientation control layer has only to be disposed between a yoke material and the fixed layer 16. A buffer layer made of, for example, Ta, TiN or TaN may be disposed between the crystal orientation control layer and the yoke material. In the case of the top pin structure, it is preferable to use MgO in which an fcc (100) face is oriented in a barrier layer. In this case, more crystal orientation control layers may be stacked to the extent that the MR does not deteriorate.

The fct (001) face also needs to be oriented when an ordered alloy such as FePt or CoPt is used as the recording layer 18. In the case of the top pin (bottom free) structure, a crystal orientation control layer has only to be disposed between the yoke material and the fixed layer 16. A buffer layer made of, for example, Ta, TiN or TaN may be disposed between the crystal orientation control layer and the yoke material. In the case of the bottom pin (top free) structure, it is preferable to use MgO in which an fcc (100) face is oriented in a barrier layer. In this case, more crystal orientation control layers may be stacked to the extent that the MR does not deteriorate.

Furthermore, in order to increase perpendicular magnetizing properties of the fixed layer 16 and the recording layer 18, a soft magnetic layer such as CoFeB or an Fe single layer needs be inserted between the above two layers and the tunnel insulating film 17.

[9] Writing

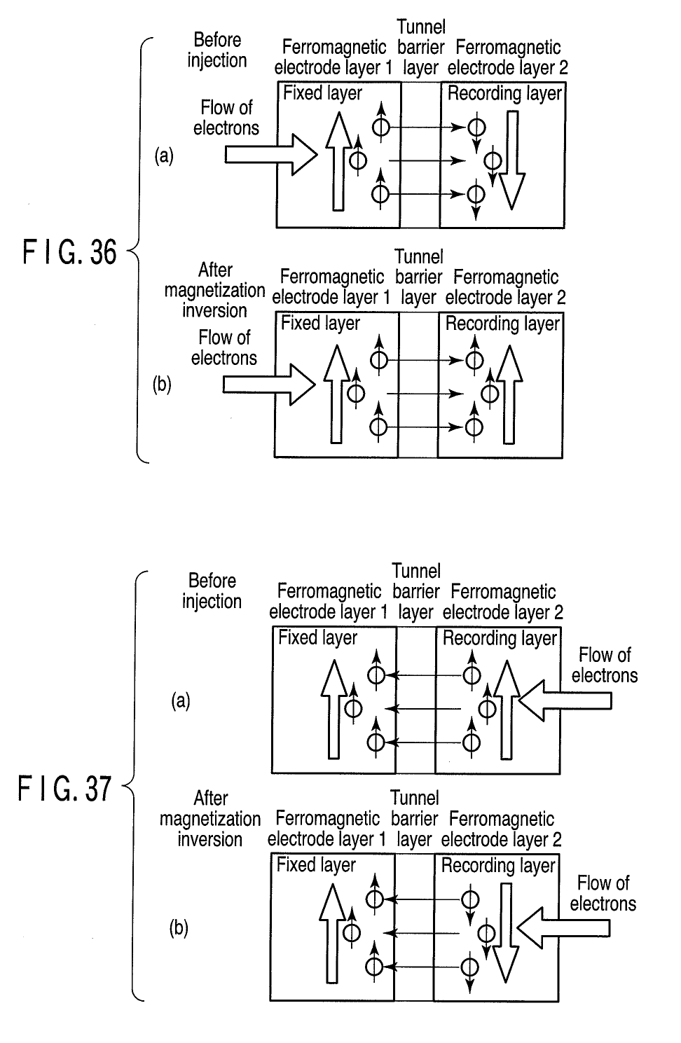

The principle of magnetization inversion by spin injection according to the present embodiment is described with (a) and (b) of FIG. 36 and (a) and (b) of FIG. 37.

First, in order to change from an antiparallel state to a parallel state, electrons having a spin in the same direction as the fixed layer are injected into the recording layer having an opposite spin from the fixed layer, as shown in (a) of FIG. 36. In this state, beyond a current density J_{cP→AP}, the magnetization of the whole recording layer is inverted, and the MTJ element is put in a parallel state, as shown in (b) of FIG. 36.

On the other hand, in order to change from a parallel state to an antiparallel state, electrons in the same direction as the fixed layer are injected into the fixed layer from the recording layer, as shown in (a) of FIG. 37. That is, electrons having a spin in the opposite direction to the direction of spin of the electrons in the recording layer are injected into the recording layer by reflection of the spin. In this state, beyond a current density J_{cAP→P}, the magnetization of the whole recording layer is inverted, and the MTJ element is put in an antiparallel state, as shown in (b) of FIG. 37.

In such a spin injection magnetization inversion scheme, the current densities J_{cP→AP}, J_{cAP→P} necessary for magnetization inversion are values determined by the kind, anisotropy and thickness of the materials constituting the fixed and recording layers. Therefore, a smaller element size leads to a total current value necessary for a write operation, which can be said to be appropriate for miniaturization.

Furthermore, in a spin-injection magnetic random access memory, a current is perpendicularly passed to an MTJ film, and depending on the direction of the current, a spin is injected into the recording layer to cause magnetization inversion. In the case of a perpendicular type (magnetization perpendicular to film surface), the direction perpendicular to the film surface has only to have uniaxial anisotropy, and there is no need for shape magnetic anisotropy in a planar direction as in a planar type (magnetization in the in-plane direction of a film). Therefore, the aspect of the MTJ element is set at 1 so that the MTJ element can be reduced to a fabrication limitation in principle. Moreover, in contrast with the planar type, there is no need for a current magnetic field interconnect for generating current magnetic fields in different directions in two axes, and operation is enabled as long as there are two terminals connecting the upper and lower electrodes of the MTJ film, such that a cell area per bit can be reduced.

Here, an inversion current of a planar spin injection film is provided by Equations (1) and (2):

$$\begin{matrix}{I}_{C}^{P - AP} \approx \frac{A α {M}_{s} V}{g ( 0 ) p} ( H + {H}_{dip} + {H}_{k} // + 2 π {M}_{s} ) & ( 1 ) \\ {I}_{C}^{AP - P} \approx \frac{A α {M}_{s} V}{g ( π ) p} ( H + {H}_{dip} - {H}_{k} // - 2 π {M}_{s} ) & ( 2 )\end{matrix}$$

wherein M_{S} indicates the saturation magnetization of the recording layer, V indicates the volume of the recording layer, α indicates the Gilbert damping constant, A indicates a constant associated with a transport model, H indicates an applied magnetic field (in-plane direction) in the in-plane direction of a wafer, H_{dip} indicates a leakage magnetic field (in-plane direction) from the fixed layer, P indicates spin polarizability, Hₖ//indicates an anisotropic magnetic field (in-plane direction), and g indicates a coefficient associated with a relative angle between the recording and fixed layers.

On the other hand, an inversion current of a perpendicular spin injection film is provided by Equations (3) and (4):

$$\begin{matrix}{I}_{C}^{P - AP} \approx \frac{ A α {M}_{s} V}{g ( 0 ) p} ( {H}_{k ⊥} - 4 π {M}_{s} - H - {H}_{dip} ) & ( 3 ) \\ {I}_{C}^{AP - P} \approx \frac{A α {M}_{s} V}{g ( π ) p} ( - {H}_{k ⊥} + 4 π {M}_{s} - H - {H}_{dip} ) & ( 4 )\end{matrix}$$

wherein M_{S} indicates the saturation magnetization of the recording layer, V indicates the volume of the recording layer, α indicates the Gilbert damping constant of the recording layer, A indicates a constant associated with a transport model, H indicates an applied magnetic field (perpendicular direction) in the in-plane direction of a wafer, H_{dip} indicates a leakage magnetic field (perpendicular direction) from the fixed layer, P indicates spin polarizability, H_{k⊥} indicates an anisotropic magnetic field (perpendicular direction), and g indicates a coefficient associated with a relative angle between the recording and fixed layers.

Thus, a spin inversion current I_{c} is an important parameter in the spin-injection magnetic random access memory.

In addition, as a tunnel barrier for TMR, polycrystalline MgO of the (001) face is interposed between polycrystalline CoFeB of the same (001) face to provide a CoFeB (001)/MgO (001)/CoFeB (001) structure. This structure has a function of a spin filter which selectively allows the passage of Δ1 (s-electron like) electrons called coherent tunneling alone. Therefore, this can be said to be a material which not only achieves higher TMR but also contributes considerably to the improvement in the efficiency of spin injection.

[10] Reading

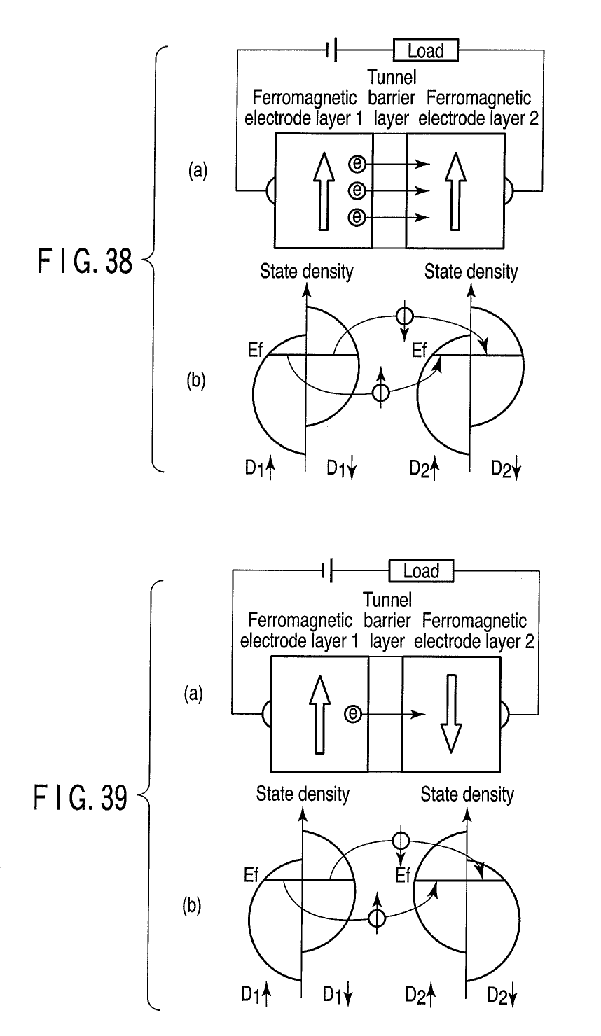

The concept of a TMR effect of the MTJ element according to the present embodiment is described with (a) and (b) of FIG. 38 and (a) and (b) of FIG. 39.

In a Julliere model, given that the direction of an electron spin does not change in the tunneling process of electrons, majority-spin (minority-spin) electrons tunnel through the band of majority-spin (minority-spin) electrons in the other ferromagnetic electrode layer when the directions of the magnetizations of the ferromagnetic electrode layers on two sides are parallel to each other ((a) and (b) of FIG. 38). On the other hand, when the directions of the magnetizations of the ferromagnetic electrode layers on two sides are antiparallel to each other, the majority-spin (minority-spin) electrons tunnel through the band of minority-spin (majority-spin) electrons in the other ferromagnetic electrode layer ((a) and (b) of FIG. 39).

As a result, the rate of change (magnetoresistive effect ratio or MR ratio) of the tunnel resistance (Rp) when the magnetizations are parallel and the tunnel resistance (Rap) when the magnetizations are antiparallel is represented by Equation (5):

$$MR ratio = ( Rap - Rp ) / Rp = 2 {P}_{1} {P}_{2} / ( 1 - {P}_{1} {P}_{2} ) \\ {R}_{α } = ( {D}_{α} ↑ ( EF ) ) - {D}_{α} ↓ ( EF ) ) / ( {D}_{α} ↑ ( EF ) ) + {D}_{α} ↓ ( EF ) \\ α = 1 , 2 \qquad ( 5 )$$

wherein P is an amount called spin polarizability, and is defined by the state density D→(Ef) of the majority-spin band in the Fermi level Ef of the electrode and by the state density D←(Ef) of the minority-spin band.

In the magnetic random access memory according to the present embodiment, the resistance change of the MTJ element due to such a TMR effect is read from the outside to read the recording state.

The present invention is not limited to the embodiments described above, and in carrying out the invention, various modifications can be made without departing from the spirit thereof. For example, the present invention is also advantageous to the process of other resistance-change memories. Specifically, in a resistance random access memory (ReRAM), metal oxides such as NiO and TiO₂ are used for a recording layer, and a write current is passed across two terminals to create a high resistance state and a low resistance state. Thus, the present invention is advantageous in that power consumption can be suppressed by using the present invention to miniaturize cells. The present invention can also be used in a phase-change random access memory (PRAM). In the PRAM, when a chalcogenide-based conducting film for the recording layer is formed after the formation of a writing plug in an insulating film, the present invention is used to form a recording layer around the plug alone, such that a micro-cell can be formed, and a low-power-consumption cell can be formed.

The embodiments of the present invention provide a resistance-change memory and a manufacturing method thereof which enable the miniaturization of a resistance-change element.

Furthermore, the embodiments described above include inventions at various stages, and suitable combinations of a plurality of components disclosed permit various inventions to be extracted. For example, when the problems described in the section BACKGROUND OF THE INVENTION can be solved and the advantages described in the section BRIEF SUMMARY OF THE INVENTION can be obtained even if some of all the components shown in the embodiments are eliminated, a configuration in which those components are eliminated can be extracted as an invention.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A resistance-change memory comprising:
an interlayer insulating film on a semiconductor substrate comprising a step;
a lower electrode layer on the interlayer insulating film comprising the step;
a fixed layer on the lower electrode layer comprising invariable magnetization;
a first insulating film on the fixed layer;
a recording layer on a portion of the first insulating film comprising variable magnetization;
a second insulating film over the recording layer and in contact with the first insulating film;
a conducting layer on the second insulating film; and
an interconnection connected to the conducting layer.

2. The resistance-change memory of claim 1, wherein
the step comprises a projecting portion.

3. The resistance-change memory of claim 1, wherein
the step comprises a recessed portion.

4. The resistance-change memory of claim 2, wherein
an area of a planar shape of the recording layer is greater than an area of a planar shape of the projecting portion.

5. The resistance-change memory of claim 3, wherein
an area of a planar shape of the recording layer is greater than an area of a planar shape of the recessed portion.

6. The resistance-change memory of claim 2, wherein
an area of a planar shape of the recording layer is smaller than an area of a planar shape of the projecting portion.

7. The resistance-change memory of claim 3, wherein
an area of a planar shape of the recording layer is smaller than an area of a planar shape of the recessed portion.

8. The resistance-change memory of claim 1, wherein
a thickness of the first insulating film between the recording layer and the fixed layer is smaller than a total thickness of the first and second insulating films between the conducting layer and the fixed layer.

9. A resistance-change memory comprising:
an interlayer insulating film on a semiconductor substrate comprising a step;
a lower electrode layer on the interlayer insulating film comprising the step;
a fixed layer on the lower electrode layer comprising invariable magnetization;
a first insulating film on the fixed layer;
a recording layer on a portion of the first insulating film and comprising variable magnetization;
a second insulating film over the recording layer and in contact with the first insulating film;
a third insulating film on the sidewall of the second insulating film; and
an interconnection connected to the recording layer via the second insulating film.

10. The resistance-change memory of claim 9, wherein
the step comprises a projecting portion.

11. The resistance-change memory of claim 9, wherein
the step comprises a recessed portion.

12. The resistance-change memory of claim 10, wherein
an area of a planar shape of the recording layer is greater than an area of a planar shape of the projecting portion.

13. The resistance-change memory of claim 11, wherein
an area of a planar shape of the recording layer is greater than an area of a planar shape of the recessed portion.

14. The resistance-change memory of claim 10, wherein
an area of a planar shape of the recording layer is smaller than an area of a planar shape of the projecting portion.

15. The resistance-change memory of claim 11, wherein
an area of a planar shape of the recording layer is smaller than an area of a planar shape of the recessed portion.

16. A resistance-change memory comprising:
an interlayer insulating film on a semiconductor substrate comprising a step;
a lower electrode layer on the interlayer insulating film comprising the step;
a first insulating film on the lower electrode layer;
a recording layer on a portion of the first insulating film comprising variable magnetization;
a second insulating film over the recording layer and in contact with the first insulating film;
a fixed layer on the second insulating film comprising invariable magnetization; and
an interconnection connected to the fixed layer.

17. The resistance-change memory of claim 16, wherein
the step comprises a projecting portion.

18. The resistance-change memory of claim 16, wherein
the step comprises a recessed portion.

19. A method of manufacturing a resistance-change memory, the method comprising:
forming a first interlayer insulating film comprising a step on a semiconductor substrate;
forming a lower electrode layer on the step;
stacking a fixed layer, a first insulating film and a recording layer on the lower electrode layer in order;
agglomerating the recording layer on the step by a thermal treatment;
stacking a second insulating film and a conducting layer on the recording layer and the first insulating film;
retaining the second insulating film and the conducting layer on the step;
retaining the first insulating film, the fixed layer and the lower electrode layer on the step in order to form a resistance-change element;
forming a second interlayer insulating film over the resistance-change element;
planarizing the second interlayer insulating film in order to expose the conducting layer; and
forming an interconnection on an exposed upper surface of the conducting layer.

20. A method of manufacturing a resistance-change memory, the method comprising:
forming a first interlayer insulating film comprising a step on a semiconductor substrate;
forming a lower electrode layer on the step;
stacking a fixed layer, a first insulating film and a recording layer on the lower electrode layer in order;
agglomerating the recording layer on the step by a thermal treatment;
stacking second and third insulating films on the recording layer and the first insulating film;
retaining the second and third insulating films on the step;
retaining the first insulating film, the fixed layer and the lower electrode layer on the step in order to form a resistance-change element;
forming a second interlayer insulating film over the resistance-change element;
planarizing the second interlayer insulating film in order to expose either the second insulating film or the recording layer; and
forming an interconnection on an exposed upper surface of either the second insulating film and the recording layer.
